(19) United States
(12) Patent Application Publication
(10) Pub. No.: US 2025/0251660 A1
(43) Pub. Date: Aug. 7, 2025

(54) MASK MANUFACTURING METHOD INCLUDING ACI TARGET ALLOCATION METHOD, AND SEMICONDUCTOR CHIP MANUFACTURING METHOD USING THE MASK MANUFACTURING METHOD

(71) Applicant: Samsung Electronics Co., Ltd., Suwon-si (KR)

(72) Inventors: Yongsu Jung, Suwon-si (KR); Moojoon Shin, Suwon-si (KR); Kyungjae Park, Suwon-si (KR); Yangwoo Heo, Suwon-si (KR)

(21) Appl. No.: 18/952,272

(22) Filed: Nov. 19, 2024

(30) Foreign Application Priority Data
Feb. 7, 2024 (KR) 10-2024-0019164

(51) Int. Cl. G03F 1/84; G03F 7/00

(52) U.S. Cl. CPC G03F 1/84; G03F 7/70441

(57) ABSTRACT

A method of manufacturing a mask for semiconductor processing includes: generating a design layout, allocating an effective after clean inspection (ACI) target to the design layout, according to a location of a lower structure layout of a semiconductor chip, and performing process proximity correction (PPC) on the design layout according to the effective ACI target.

### REFERENCE TO PRIORITY APPLICATION

This application claims priority under 35 U.S.C. § 119 to Korean Patent Application No. 10-2024-0019164, filed Feb. 7, 2024, the disclosure of which is hereby incorporated herein by reference.

### BACKGROUND

The inventive concept relates to mask manufacturing methods and semiconductor chip manufacturing methods using masks and, more particularly, to mask manufacturing methods including after clean inspection (ACI) operations and associated semiconductor chip manufacturing methods.

When patterns of a design layout are transferred onto a wafer through a photolithography process to form preset patterns on the wafer, a gap may occur between the patterns transferred onto the wafer and the patterns of the design layout. This gap may be due to one or more optical proximity effects associated with a photo lithography process and/or the loading effect of an etching process.

In order to accurately transfer the patterns of the design layout onto the wafer, process proximity correction (PPC) is performed by considering the deformation of transfer patterns onto a wafer. The process proximity correction may be used to predict and analyze the optical proximity effect and loading effect in advance and correct the patterns of the design layout on a mask according to the analysis result.

### SUMMARY

The inventive concept provides a mask manufacturing method including a method of precisely allocating an after clean inspection (ACI) target of patterns of a design layout when (or before) process proximity correction (PPC) is performed.

Also, the inventive concept provides a semiconductor chip manufacturing method using masks formed by the mask manufacturing method.

According to an aspect of the inventive concept, a mask manufacturing method includes: generating a design layout, allocating an effective after clean inspection (ACI) target to the design layout, and performing process proximity correction (PPC) on the design layout according to the effective ACI target. According to some embodiments, during the allocating of the effective ACI target, the effective ACI target of the design layout is repeatedly changed and allocated according to a location of a lower structure layout of a semiconductor chip.

According to another aspect of the inventive concept, a mask manufacturing method includes generating a design layout, allocating an effective after clean inspection (ACI) target to the design layout, and performing process proximity correction (PPC) on the design layout according to the effective ACI target. The allocating of the effective ACI target includes: generating a lower structure layout of a semiconductor chip, receiving etch skew measurement data on the design layout based on the lower structure layout of the semiconductor chip, allocating a preliminary ACI target of the design layout according to a location of the lower structure layout of the semiconductor chip based on the etch skew measurement data, and obtaining the effective ACI target by performing numerical integration on the preliminary ACI target and a probability density function of the design layout according to the location of the lower structure layout of the semiconductor chip.

According to a further aspect of the inventive concept, a semiconductor chip manufacturing method includes generating a design layout, allocating an effective after clean inspection (ACI) target to the design layout, performing process proximity correction (PPC) on the design layout according to the effective ACI target, performing optical proximity correction (OPC) on the design layout according to the effective ACI target, manufacturing a mask by using a design layout obtained by performing the OPC, and manufacturing a semiconductor chip by using the mask. According to some embodiments, the allocating of the effective ACI target includes generating a lower structure layout of a semiconductor chip, receiving etch skew measurement data on the design layout based on the lower structure layout of the semiconductor chip, allocating a preliminary ACI target of the design layout according to a location of the lower structure layout of the semiconductor chip based on the etch skew measurement data, and obtaining the effective ACI target by performing numerical integration on the preliminary ACI target and a probability density function of the design layout according to the location of the lower structure layout of the semiconductor chip.

### BRIEF DESCRIPTION OF THE DRAWINGS

Embodiments of the inventive concept will be more clearly understood from the following detailed description taken in conjunction with the accompanying drawings in which:

FIG. 1 is a block diagram illustrating a computing device that may perform process proximity correction (PPC) and optical proximity correction OPC while precisely allocating an after clean inspection (ACI) target according to an embodiment;

FIG. 2 is a flowchart illustrating a mask manufacturing method and a semiconductor chip manufacturing method including the mask manufacturing method according to an embodiment;

FIG. 3 is a perspective view illustrating a lower structure layout of a semiconductor chip, which can be considered in a design layout when a mask is manufactured, according to an embodiment;

FIG. 4 is a plan view illustrating a lower structure layout of a semiconductor chip that can be considered in a design layout when a mask is manufactured, according to an embodiment;

FIG. 5 is a flowchart specifically illustrating an operation of allocating an effective ACI target to a design layout when a mask is manufactured, according to the inventive concept;

FIG. 6 is a diagram illustrating a preliminary ACI target table that is used when an effective ACI target is allocated in FIG. 5;

FIG. 7 is a diagram illustrating allocation of a preliminary ACI target that is used when allocating an effective ACI target which is illustrated in FIG. 5;

FIG. 8 is a diagram illustrating allocation of an effective ACI target according to a lower structure of the semiconductor chip which is illustrated in FIG. 5;

FIG. 9 is a flowchart specifically illustrating an operation of calculating an effective ACI target of a design layout when a mask is manufactured, according to the inventive concept;

FIG. 10 is a plan view specifically illustrating the operation of calculating the effective ACI target of the design layout when the mask is manufactured in FIG. 9, according to the inventive concept;

FIG. 11 is a plan view illustrating a lower structure boundary according to the effective ACI target of the design layout when the mask is manufactured, according to the inventive concept;

FIGS. 12 and 13 are diagrams respectively illustrating the greatest effective ACI target and the smallest effective ACI target illustrated in FIG. 11;

FIG. 14 is a diagram illustrating a result of one-dimensionally allocating an effective ACI target when a mask is manufactured, according to an embodiment;

FIG. 15 is a diagram illustrating a result of two-dimensionally allocating an effective ACI target when a mask is manufactured, according to an embodiment; and

FIG. 16 is a cross-sectional view illustrating a semiconductor chip according to an embodiment.

### DETAILED DESCRIPTION OF EMBODIMENTS

Hereinafter, embodiments of the inventive concept are described in detail with reference to the attached drawings. Only one of following embodiments may be implemented, and also, combinations of two or more of the following embodiments may be implemented. Accordingly, the inventive concept should not be construed as being limited to one embodiment. Also, components described in the singular herein may include the plural.

In general, a semiconductor process for manufacturing a semiconductor chip may include a combination of various procedures, such as etching, deposition, planarization, growth, and ion implantation. The etching may include a process of forming a photoresist pattern on an etching target film by using a mask and forming a pattern by removing the etching target film that is not covered by the photoresist pattern by using chemicals, etching gas, plasma gas, ion beam, or so on. The etching may include a process of removing the photoresist pattern used to etch the etching target film, and then cleaning the pattern. During the etching process, a process error may occur due to various factors.

Factors causing the process error may be caused by the characteristics of a process but may also be due to characteristics of the photoresist pattern or the pattern formed by etching. In some cases, process errors caused by the characteristics of the pattern may be compensated for by modifying or changing a design layout of the pattern on a mask. Modifying or changing the design layout of the pattern on the mask may be referred to as process proximity correction (PPC).

It is important to precisely allocate an after clean inspection (ACI) target of a pattern on a mask when or before the PPC is performed. Also, even when optical proximity correction (OPC) is performed after the PPC is performed, it is important to precisely allocate the ACI target of a pattern on a mask.

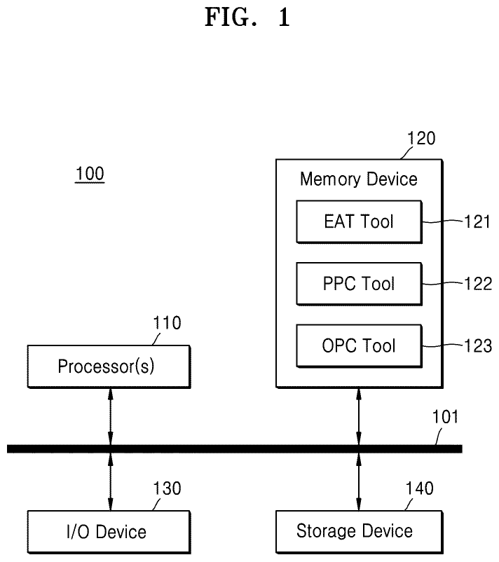

FIG. 1 is a block diagram illustrating a computing device that may perform PPC and OPC while precisely allocating an ACI target according to an embodiment.

Specifically, a computing device 100 may include at least one processor 110, a memory device 120, an input/output device 130, and a storage device 140, which are connected to a system bus 101. The computing device 100 may be used to design a semiconductor chip or a mask. The computing device 100 may set an ACI target when designing a mask, or perform PPC or OPC.

The computing device 100 may include various design programs and simulation programs. The processor 110, the memory device 120, the input/output device 130, and the storage device 140 may be electrically connected to each other through the system bus 101 and may exchange data with each other. A configuration of the system bus 101 is not limited to the above description and may further include other members for efficient management.

The processor 110 may control all operations of the computing device 100. The processor 110 may execute at least one instruction. For example, the processor 110 may execute software (an application program, an operating system, and a device driver) to be executed by the computing device 100. The processor 110 may execute an operating system loaded on the memory device 120. The processor 110 may execute various application programs to be run based on an operating system.

The processor 110 may drive an effective ACI target setting tool (an EAT tool) 121, a PPC tool 122, and an OPC tool 123 which are read from the memory device 120. In the present embodiment, the effective ACI target setting tool 121, the PPC tool 122, and the OPC tool 123 are illustrated separately but may be combined into one tool. In some embodiments, the processor 110 may include a central processing unit (CPU), a microprocessor, an application processor (AP), or any similar processing device. The memory device 120 may store at least one instruction. For example, the memory device 120 may store an operating system or application programs. When the computing device 100 is booted, an operating system image stored in the storage device 140 may be loaded into the memory device 120 according to a boot sequence.

All input/output operations of the computing device 100 may be supported by an operating system. Similarly, an application program selected by a user may be loaded into the memory device 120 to provide a basic service. In particular, a design tool for semiconductor design, a PPC tool 122 that performs process proximity correction and an OPC tool 123 that performs OPC may be loaded into the memory device 120 from the storage device 140.

Also, the memory device 120 may include volatile memory, such as dynamic random access memory (DRAM) or static random access memory (SRAM), or nonvolatile memory, such as flash memory, phase change random access memory (PRAM), resistance random access memory (RRAM), nano floating gate memory (NFGM), polymer random access memory (PoRAM), magnetic random access memory (MRAM), or ferroelectric random access memory (FRAM).

The design tool may perform a function of changing shapes and locations of specific patterns of a design layout to be different from the shapes and locations of the patterns defined by a design rule. Also, the design tool may perform the design rule check (DRC) under a changed bias data condition.

The PPC tool 122 may perform a PPC function for patterns of the design layout to be implemented on a mask. In some embodiments, the PPC tool 122 may perform PPC based on a change in ACI critical dimension (CD) according to an after development inspection (ADI) CD.

In some embodiments, the PPC tool 122 may perform PPC based on a change in ACI CD according to etch loading. In some embodiments, the PPC tool 122 may perform the PPC based on the change in ACI CD according to a vertical structure. The OPC tool 123 may correct patterns included in the design layout by reflecting an error according to an optical proximity effect (OPE).

The input/output device 130 may control a user input to and an output from a user interface device. For example, the input/output device 130 may include input components, such as a keyboard, a keypad, a mouse, a touch screen, and so on to receive information from a designer. By using the input/output device 130, a designer may receive information on semiconductor regions or data paths that require adjusted operation characteristics.

Also, the input/output device 130 may include output components, such as a printer, a display, and so on to display the processing and a processing result of a design tool, the effective ACI target setting tool 121, the PPC tool 122, or the OPC tool 123. The storage device 140 may be provided as a storage medium of the computing device 100. The storage device 140 may store application programs, operating system images, and various data. The storage device 140 may include a mass storage device, such as a memory card (for example, a multimedia card (MMC), an embedded multimedia card (eMMC), a secure digital (SD) card, a micro SD card, or so on), a hard disk drive (HDD), a solid state drive (SSD), a universal flash storage (UFS), or so on.

In addition, after a core on peripheral (COP) process of semiconductor chips is introduced, high aspect ratio contact (HARC) layers may be combined into one mask for technology development. In the COP process, a CD change due to etching increases because patterns with deep depths and various lower structures coexist. In order to correct the CD change, PPC may be performed. The PPC may mean predicting a CD value of an ACI state that is changed by etching and correcting an ADI CD to obtain the CD of a predicted result.

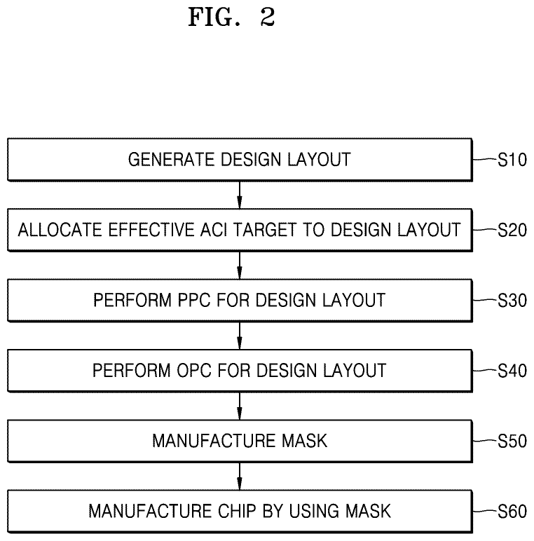

FIG. 2 is a flowchart illustrating a mask manufacturing method and a semiconductor chip manufacturing method including the mask manufacturing method according to an embodiment. Specifically, the semiconductor chip manufacturing method may proceed as follows. A design layout of a mask corresponding to a pattern (or a circuit pattern) of a semiconductor chip to be formed on a wafer may be generated (S10). The design layout may be generated by being provided by a host computer or server within semiconductor manufacturing equipment.

The design layout may include many patterns as physical representations of a circuit (or a circuit pattern) designed for a semiconductor chip that may be transferred onto a wafer. For example, the design layout may be provided by a computer aided design (CAD) system as coordinate values of contours of patterns that form the design layout. In particular, the patterns may include repetitive patterns in which the same shape is repeated. Here, patterns may include a combination of polygons, such as triangles or squares.

An effective ACI target is allocated to the design layout (S20). The effective ACI target may mean an effective ACI CD value. Allocation of the effective ACI target may mean allocation effective ACI CD values to patterns included in the design layout. Allocation of the effective ACI target means allocation of the effective ACI CD values to the patterns included in the design layout depending on a location of a lower structure layout of a semiconductor chip.

Allocation of the effective ACI target may be performed by the effective ACI target setting tool 121 of FIG. 1, as described above. Allocation of the effective ACI target may cause PPC to be performed more accurately depending on a location of a lower structure layout of a semiconductor chip. Although the present embodiment describes how an allocation of an effective ACI target is performed separately from PPC, the allocation of the effective ACI target may be performed together while PPC is performed. The allocation of the effective ACI target is described in more detail below.

Thereafter, PPC may be performed for the design layout including patterns to which the effective ACI target is allocated (S30). In some embodiments, rule-based PPC may be performed. The rule-based PPC may be based on information on edges of patterns, such as widths and spaces of the patterns. In another embodiment, model-based PPC may be performed. The model-based PPC may be performed by using pixel-based images of the design layout. In the model-based PPC, CD may be predicted by processing images, and correction may be made according to a predicted result.

The rule-based PPC may perform less operations than the model-based PPC. Moreover, because the rule-based PPC typically uses less information than the model-based PPC, the accuracy of the rule-based PPC may be lower than the accuracy of the model-based PPC. In addition, the model-based PPC may use a larger amount of information than the rule-based PPC when performing operations. Therefore, the accuracy of the model-based PPC may be higher than the accuracy of the rule-based PPC, but the computational amount of the model-based PPC may be greater than the computational amount of the rule-based PPC. PPC may be performed on the pattern of the design layout to be implemented on the mask. In the PPC, the amount of change between an ACI CD and an ADI CD, that is, an etch skew, may be calculated.

According to some embodiments, in the PPC, the amount of change in ACI CD according to etch loading may be calculated. According to some embodiments, in the PPC, the amount of change in ACI CD according to a vertical structure may be calculated. According to some embodiments, in the PPC, a weak pattern may be detected based on the amount of change between the ACI CD and the ADI CD, etch load sensitivity, or vertical sensitivity. According to some embodiments, in the PPC, ADI/ACI monitoring for the weak pattern may be performed. According to some embodiments, in the PPC, the ACI CD changed by etching may be predicted, and the ADI CD may be corrected to obtain the predicted ACI CD.

Thereafter, OPC may be performed for the design layout including patterns to which an effective ACI target is allocated (S40). The OPC means correcting patterns included in the design layout by reflecting an error due to an optical proximity effect. As patterns are miniaturized, an optical proximity effect may occur due to the influence between closely adjacent patterns during an exposure process. Therefore, the optical proximity effect may be reduced by performing the optical proximity correction to correct the design layout.

For example, the OPC may include expanding the entire size of the patterns that form the design layout and processing corners. For example, the OPC may include moving the corners of each pattern or adding polygons. Through the OPC, pattern distortion caused by light diffraction and interference that occurs during exposure may be corrected, and an error caused by pattern density may be corrected. The OPC may include a rule-based OPC and a model-based OPC. Thereafter, mask data may be input to an OPC model and the contour of a target pattern may be predicted through simulation.

In some embodiments, after OPC is performed, OPC verification may be further performed. Thereafter, location correction may be further performed. In the location correction, a location of the optical proximity-corrected pattern may be moved by considering physical deformation and change of a lower structure in which patterns are aligned. The deformation of the lower structure occurs due to factors of a semiconductor chip manufacturing process. Accordingly, progressive misalignment, in which actual pattern locations of the lower structure change from the original layout, may occur.

In the location correction, only the location of an optical proximity-corrected pattern may be moved without changing a shape of the optical proximity-corrected pattern. The final design layout data corrected by the optical proximity correction and location correction may be transferred to an exposure apparatus for manufacturing masks for a lithography process, such as photo masks and electron beam masks.

A mask may be manufactured by using the corrected design layout (S50). For example, after OPC is performed, design data obtained through the OPC may be transferred as mask tape out (MTO) design data. The MTO design data may be mask design data obtained by completing the OPC.

The MTO design data may have a graphic data format used in electronic design automation (EDA) software, and so on. For example, the MTO design data may have data formats, such as GDS, and OASIS. After the MTO design data is transferred, mask data preparation (MDP) may be performed. The MDP may include format conversion, augmentation, and verification. This format conversion may also be called fracturing and may refer to a process of fracturing the MTO design data into respective regions and changing the respective regions to a format for an electron beam exposure apparatus. For example, the fracturing may include data manipulation, such as scaling, sizing of data, rotation of data, pattern reflection, color inversion, and so on.

During the format conversion, data may be corrected for systematic errors during transfer from design data to images on a wafer. Here, the systematic errors may be caused by distortions occurring in an exposure process, a mask development and etching process, a wafer imaging process, and so on. In other words, the exposure process may be performed on a mask substrate by using the corrected design layout data. For example, the exposure process may mean electron beam (E-beam) writing. Here, the electron beam writing may be performed by using a gray writing method using a multi-beam mask writer (MBMW).

Also, the electron beam writing may also be performed by using a variable shape beam (VSB) exposure apparatus. After the exposure process, a series of processes, such as development, etching, cleaning, and baking, may be further performed, and thereby, a mask may be manufactured. In some embodiments, before the corrected design layout data is transferred, verification for the corrected design layout data may be further performed.

Thereafter, a semiconductor chip may be manufactured by using the mask (S60). Here, the semiconductor chip may include volatile memory, such as DRAM or SRAM, or non-volatile memory, such as flash memory, and also include a logic semiconductor, such as a microprocessor, for example, a CPU, a controller, or an application specific integrated circuit (ASIC).

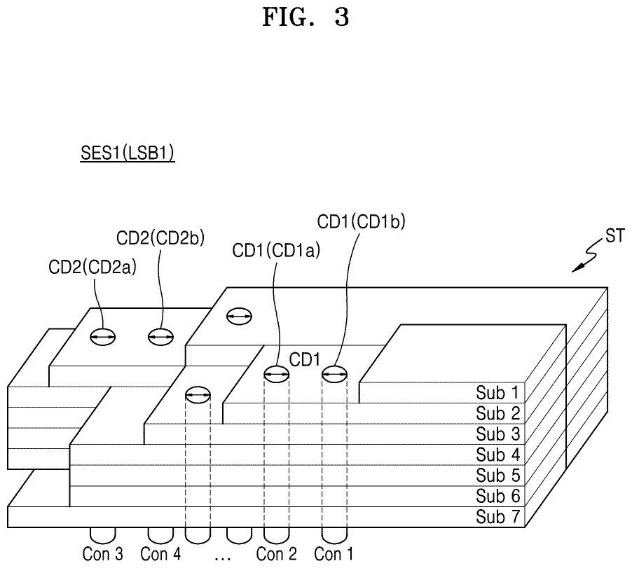

FIG. 3 is a perspective view illustrating a lower structure layout of a semiconductor chip that has to be considered in design layout when a mask is manufactured, according to an embodiment. Specifically, as described above, PPC is performed before the OPC to correct an etch skew occurring in an etching process after the photolithography process, that is, a difference between ACI CD (an ACI target) and ADI CD (an ADI target). In the PPC, the ADI target, which may achieve the ACI target, may be predicted through a basic geometry structure, such as density, a width, and a space of a pattern of a design layout.

As an example of a semiconductor chip SES1, a vertical flash memory is illustrated in FIG. 3. The semiconductor chip SES1 may include a lower structure layout LSB1. The lower structure layout LSB1 may include a stacked body ST. The stacked body ST may include a plurality of sublayers, for example, first to seventh sublayers (sub 1 to sub 7). A plurality of contact patterns separated from each other, for example, first, second, third, and fourth contact patterns Con 1, Con 2, Con 3, and Con 4, which are separated by a mask manufactured according to the inventive concept, may be formed in the stacked body ST. Because etch selectivity and etch profiles of the first, second, third, and fourth contact patterns Con 1, Con 2, Con 3, and Con 4 change according to the lower structure layout LSB1, preliminary ACI targets CD1 and CD2 have to be set by considering the change in etch selectivity and etch profiles when manufacturing a mask.

That is, because the first, second, third, and fourth contact patterns Con 1, Con 2, Con 3, and Con 4 have different etch skews, the preliminary ACI targets CD1 and CD2 have to be set by considering the different etch skews when manufacturing a mask. For example, the first contact pattern Con 1 and the second contact pattern Con 2 may be formed in a second sublayer sub 2 in a plan view, and accordingly, all preliminary ACI targets may be equally set to the CD1. The third contact pattern Con 3 and the fourth contact pattern Con 4 may be formed in a third sublayer sub 3 in a plan view, and accordingly, the preliminary ACI targets may be equally set to the CD2. That is, the preliminary ACI targets set in the second sublayer sub 2 and the third sublayer sub 3 may be a binary ACI target that is either the CD1 or the CD2. The CD2, which is the preliminary ACI target, may be set differently from the CD1, which is the preliminary ACI target.

Furthermore, in the mask manufacturing method of the inventive concept, first and second effective ACI targets CD1a and CD1b may be set by correcting the preliminary ACI targets CD1 and CD2 by geometrically considering formation locations of the first, second, third, and fourth contact patterns Con 1, Con 2, Con 3, and Con 4 and the surrounding environment.

The preliminary ACI target CD1 of the first contact pattern Con 1 may be corrected to be the first effective ACI target CD1a. The preliminary ACI target CD1 of the second contact pattern Con 2 may be corrected to be the second effective ACI target CD1b. Because the first contact pattern Con 1 has a different surrounding environment from the second contact pattern Con 2, the effective ACI targets CD1a and CD1b of the first contact pattern Con 1 and the second contact pattern Con 2 may be different from each other.

The preliminary ACI target CD2 of the third contact pattern Con 3 may be corrected to be a third effective ACI target CD2a. The preliminary ACI target CD2 of the fourth contact pattern Con 4 may be corrected to be a fourth effective ACI target CD2b. Because the third contact pattern Con 3 has a different surrounding environment from the fourth contact pattern Con 4, the effective ACI targets CD2a and CD2b of the third contact pattern Con 3 and the fourth contact pattern Con 4 may be different from each other.

The method of manufacturing a mask of the inventive concept may include an operation of allocating (or correcting) an effective ACI target for the design layout of the mask. Accordingly, the mask manufacturing method of the inventive concept considers a formation location or a surrounding environment of the lower structure layout LSB1 of a semiconductor chip or the first, second, third, and fourth contact patterns Con1, Con 2, Con 3, and Con4, and thus, a mask may be manufactured to better match a pattern (a circuit pattern) of the semiconductor chip SES1.

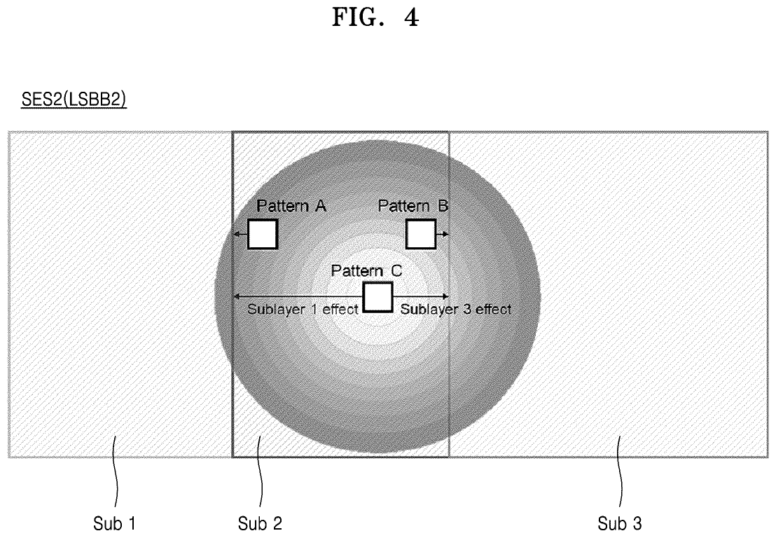

FIG. 4 is a plan view illustrating a lower structure layout of a semiconductor chip to be considered in design layout when a mask is manufactured, according to an embodiment. Specifically, a semiconductor chip SES2 may include a two-dimensional lower structure layout LSB2. The lower structure layout LSB2 may include first, second, and third sublayers Sub 1, Sub 2, and Sub 3. The first, second, and third sublayers Sub 1, Sub 2, and Sub 3 may have different lower structures from each other.

In the lower structure layout LSB2, a pattern A, a pattern B, and a pattern Care all arranged in the second sublayer sub 2, and a preliminary ACI target may be set according thereto. As described above, preliminary ACI targets of the pattern A, the pattern B, and the pattern C may be evaluated to have the same lower structure and may be set identically. The pattern A, the pattern B, and the pattern C may correspond to the first, second, third, and fourth contact patterns Con 1, Con 2, Con 3, and Con4 illustrated in FIG. 3.

The pattern A is at a border with the first sublayer Sub 1, the pattern B is at a border with the third sublayer Sub 3, and the pattern C may be close to the center of the second sub layer Sub 2. When the pattern A, the pattern B, and the pattern C are recognized as the same lower structure belonging to the second sublayer sub 2 and the same preliminary ACI target is allocated thereto, etching process errors may not be reflected at boundaries of the first, second, and third sublayers Sub 1, Sub 2, and Sub 3.

The pattern A may be influenced by the first sublayer Sub 1, the pattern B may be influenced by the third sublayer Sub 3, and the pattern C may be influenced by the first sublayer Sub 1 and the third sublayer Sub 3. Accordingly, as described above, the mask manufacturing method of the inventive concept may allocate an effective ACI target by correcting a preliminary ACI target in the design layout of a mask.

The effective ACI targets of the pattern A, the pattern B, and the pattern C may be influenced by the first sublayer Sub 1, the second sublayer Sub 2, and the third sublayer Sub 3. In particular, the mask manufacturing method of the inventive concept may set continuous effective ACI targets at the boundaries of the first, second, and third sublayers Sub 1, Sub 2, and Sub 3, and thus, a mask may be manufactured to better match a pattern (a circuit pattern) of a semiconductor chip.

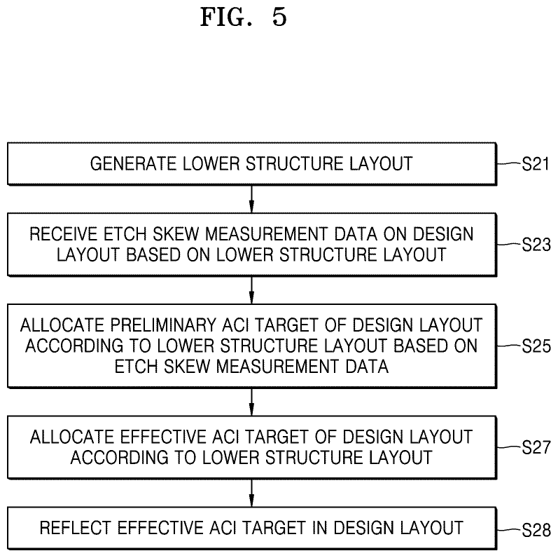

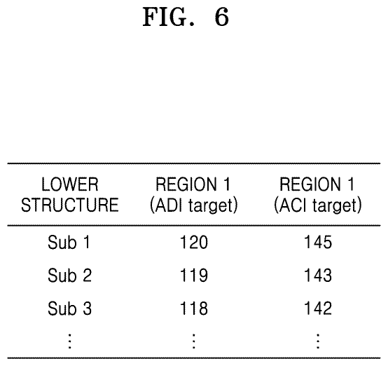

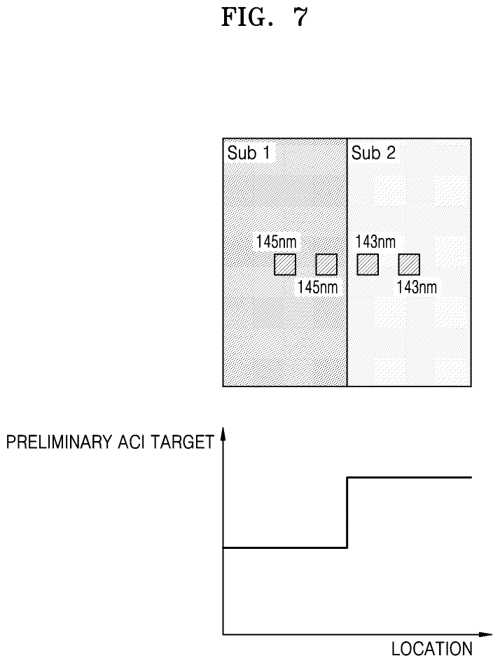

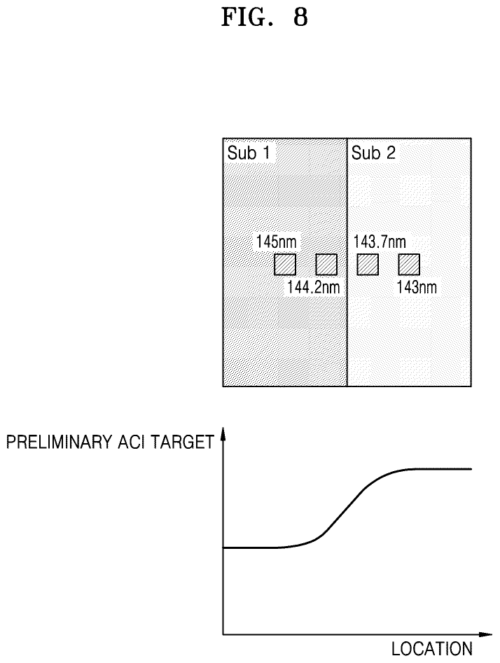

FIG. 5 is a flowchart specifically illustrating an operation of allocating an effective ACI target to a design layout when a mask is manufactured, according to the inventive concept, FIG. 6 is a diagram illustrating a preliminary ACI target table that is used when the effective ACI target is allocated in FIG. 5, FIG. 7 is a diagram illustrating allocation of the preliminary ACI target that is used when allocating the effective ACI target which is illustrated in FIG. 5, and FIG. 8 is a diagram illustrating allocation of the effective ACI target according to a lower structure of the semiconductor chip which is illustrated in FIG. 5.

Specifically, an operation of allocating an effective ACI target to a design layout may include an operation of generating a lower structure layout (LSB1 or LSB2 in FIGS. 3 and 4) (S21). As described in FIGS. 3 and 4, the lower structure layout may mean generating or receiving a layout corresponding to a lower structure of the semiconductor chip SES1 or SES2. Next, the operation of allocating the effective ACI target may include receiving etch skew measurement data on a design layout based on a lower structure layout (S23). The operation of receiving the etch skew measurement data may mean receiving an ADI target and an ACI target actually measured according to the lower structure of the semiconductor chip during manufacturing of the semiconductor chip.

As illustrated in FIG. 6, the etch skew measurement data may be a preliminary ACI target table indicating an ADI target value and an ACI target value of a certain region 1 when lower structures of a semiconductor chip are the first sublayer Sub 1, the second sublayer Sub 2, and the third sublayer Sub 3 in a plan view. For example, when the lower structure of the semiconductor chip is the first sublayer Sub 1 in a plan view, the ACI target may be 145 nm and the ADI target may be 120 nm. Accordingly, when the lower structure of the semiconductor chip is the first sublayer Sub 1 in a plan view, an etch skew, which is a difference between the ACI target and the ADI target, may be 25 nm. Also, when the lower structure of the semiconductor chip is the second sublayer Sub 2 in a plan view, the ACI target may be 143 nm and the ADI target may be 119 nm. Accordingly, when the lower structure of the semiconductor chip is the second sublayer Sub 2, the etch skew, which is the difference between the ACI target and the ADI target, may be 24 nm.

An operation of allocating an effective ACI target may include an operation of allocating a preliminary ACI target of a design layout according to a lower structure layout based on the etch skew measurement data (S25). As illustrated in an upper drawing of FIG. 7, when a lower structure of a semiconductor chip is the first sub layer Sub 1 in a plan view, the preliminary ACI target of a patterns included in the first sublayer Sub 1 may be 145 nm.

As illustrated in an upper drawing of FIG. 7, when a lower structure of a semiconductor chip is the second sub layer Sub 2 in a plan view, the preliminary ACI target of a pattern included in the second sublayer Sub 2 may be 143 nm. As illustrated in a lower drawing of FIG. 7, the preliminary ACI target may have discontinuous values depending on a pattern locations of the lower structure of the semiconductor chip. The preliminary ACI target may have a binary ACI target depending on a pattern location of the lower structure of the semiconductor chip. The preliminary ACI target may have discontinuous values at a boundary between the first sublayer Sub 1 and the second sublayer Sub 2.

An operation of allocating an effective ACI target may include an operation of allocating an effective ACI target of a design layout according to a lower structure layout (S27). The effective ACI target may be allocated differently from the preliminary ACI target depending on lower structures of a semiconductor chip.

As illustrated in an upper drawing of FIG. 8, when a lower structure of a semiconductor chip is the first sublayer Sub 1 in a plan view, effective ACI targets of patterns included in the first sublayer Sub 1 may be respectively 145 nm and 144.2 nm different from each other. In particular, an effective ACI target of a pattern at a border between the first sublayer Sub 1 and the second sublayer Sub 2 may be 144.2 nm and may be less than 145 nm which is an effective ACI target of a pattern at the center of the first sublayer Sub 1.

As illustrated in the upper drawing of FIG. 8, when the lower structure of the semiconductor chip is the second sublayer Sub 2 in a plan view, effective ACI targets of patterns included in the second sublayer Sub 2 may be 143.7 nm and 143 nm. In particular, an effective ACI target of a pattern at a border between the first sublayer Sub 1 and the second sublayer Sub 2 may be 143.7 nm and may be greater than 143 nm which is an effective ACI target of a pattern at the center of the second sublayer Sub 2.

The effective ACI target may have continuous values depending on pattern locations of the lower structure of the semiconductor chip, as illustrated in the lower drawing of FIG. 8. The effective ACI target may have continuous values at the boundary between the first sublayer Sub 1 and the second sublayer Sub 2. The allocated effective ACI target may be reflected in a design layout (S28). The allocated effective ACI target may also be reflected through the PPC. According to the mask manufacturing method of the inventive concept, continuous effective ACI targets may be set at the boundary between the first sublayer Sub 1 and the second sublayer Sub 2, and thus, a mask may be manufactured to better match a pattern (a circuit pattern) of a semiconductor chip.

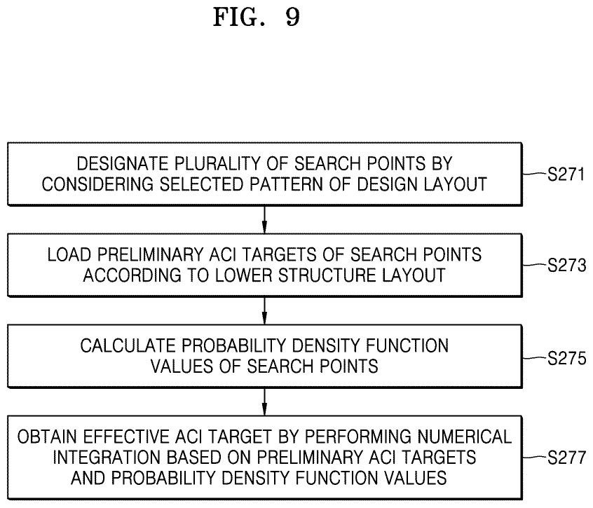

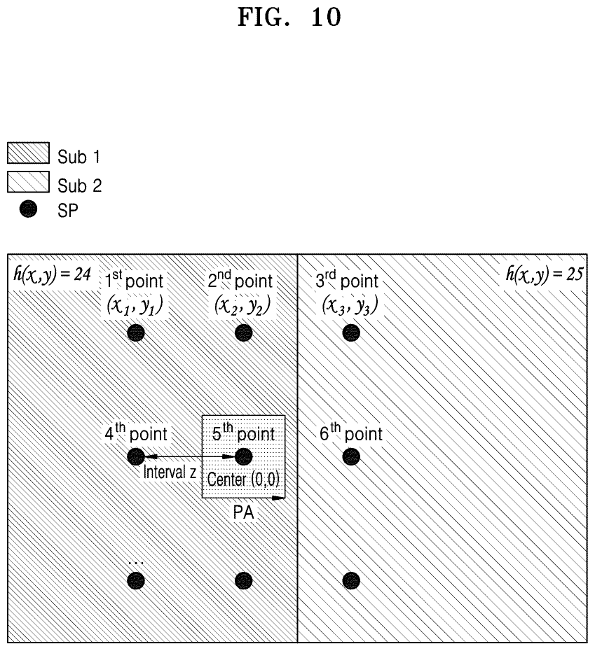

FIG. 9 is a flowchart specifically illustrating an operation of calculating an effective ACI target of a design layout when a mask is manufactured, according to the inventive concept, and FIG. 10 is a plan view specifically illustrating the operation of calculating the effective ACI target of the design layout when the mask is manufactured in FIG. 9, according to the inventive concept.

Specifically, the operation of calculating the effective ACI target for the design layout may include an operation of designating a plurality of search points SP by considering a selected pattern PA of the design layout (S271). As illustrated in FIG. 10, the pattern PA may be selected from a lower structure layout of a semiconductor chip including the first sublayer Sub 1 and the second sublayer Sub 2.

The selected pattern PA may have center coordinates (0, 0). N² (N is a natural number) search points SP may be designated in a grid form centered on the selected pattern PA. In FIG. 10, nine search points SP may be designated centered on the selected pattern PA for the sake of convenience.

For example, among the nine search points SP, coordinates of the 1st point may be (x1, y1), coordinates of the 2nd point may be (x2, y2), and coordinates of the 3rd point may be (x3, y3). Nine search points SP may be arranged in a grid form with a constant interval (an interval Z).

The operation of calculating the effective ACI target of the design layout may include an operation of loading preliminary ACI targets of the search points SP according to the lower structure layout (S273). Here, information, on which substructure each of the nine search points SP centered on a selected pattern SP is placed, may be searched and checked, and then a preliminary ACI target according to the lower structure may be loaded.

The preliminary ACI target may be represented as a function of h(x, y). For example, h(x, y), which is a function of a preliminary ACI target of a pattern placed in the first sublayer Sub 1, may be represented as 25. For example, h(x, y), which is a function of a preliminary ACI target of a pattern placed in the second sublayer Sub 2, may be represented as 24. h(x, y), which is a function of a preliminary ACI target, may correspond to the etch skew.

The operation of calculating the effective ACI target of the design layout may include an operation of calculating probability density function values of the search points (S275). The probability density function value of the nine search points SP centered on the selected pattern SP may be calculated. A probability density function may use a Gaussian blur algorithm. The probability density function may use a 2-dimensional Gaussian probability density function (PDF).

In the operation of calculating the effective ACI target of the design layout, the effective ACI target may be obtained by performing numerical integration on the preliminary ACI targets and the probability density function values (S277). The effective ACI target of the inventive concept may be calculated by numerical integration for each of the search points SP by using Equation 1 below.

∫h(x,y)f(x,y)dxdy Equation 1:

Here, h(x, y) may be a function representing the preliminary ACI target described above, and f(x, y) may be a two-dimensional Gaussian probability density function. The etch skew corresponding to the effective ACI target calculated by Equation 1 may be calculated.

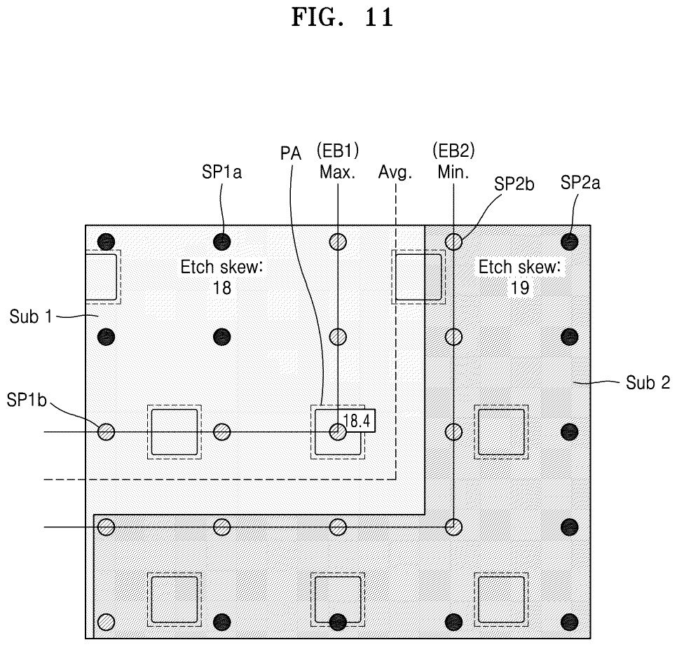

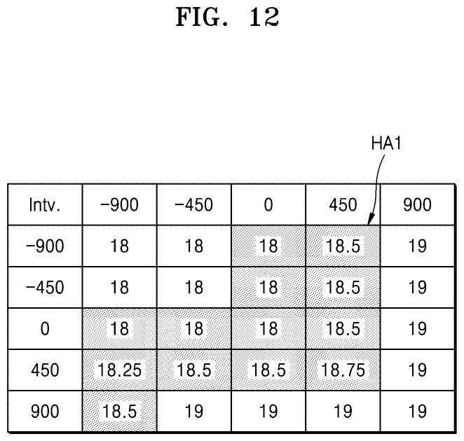

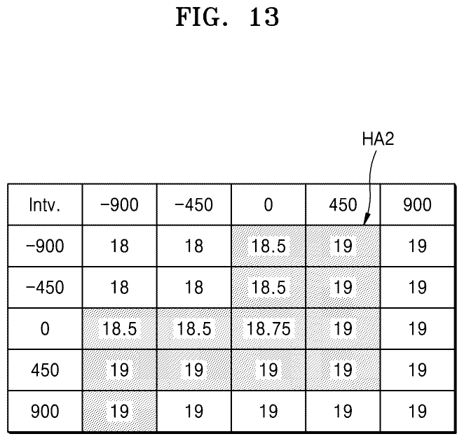

FIG. 11 is a plan view illustrating a lower structure boundary according to an effective ACI target of a design layout when a mask is manufactured, according to the inventive concept, and FIGS. 12 and 13 are diagrams respectively illustrating the greatest effective ACI target and the smallest effective ACI target illustrated in FIG. 11. Specifically, as illustrated in FIG. 11, a pattern PA may be selected from a lower structure layout of a semiconductor chip including the first sublayer Sub 1 and the second sublayer Sub 2.

N² (N is a natural number) search points SP may be designated in a grid form centered on the selected pattern PA. In FIG. 11, 25 search points SP1a, SP1b, SP2a, and SP2b may be designated centered on the selected pattern PA for the sake of convenience. An average effective ACI target of the selected pattern PA, which is an etch skew, may be 18.4 nm.

The first sublayer Sub 1) may include the search points SP1a and SP1b, and the second sublayer Sub 2 may include the search points SP2a and SP2b. The first sublayer Sub 1 may have an etch skew of 18 nm corresponding to a preliminary ACI target. The second sublayer Sub 2 may have an etch skew of 19 nm corresponding to the preliminary ACI target.

FIG. 12 is a diagram illustrating the smallest of the effective ACI target calculated according to FIGS. 9 and 10 in the design layout of FIG. 11, and FIG. 13 is a diagram illustrating the greatest value of the effective ACI target calculated according to FIGS. 9 and 10 in the design layout of FIG. 11. In FIGS. 12 and 13, the effective ACI target may correspond to the greatest and smallest etch skews of the search points SP1a, SP1b, SP2a, and SP2b.

In FIGS. 12 and 13, values in a horizontal direction (a row direction) and a vertical direction (a column direction) correspond to intervals of the search points SP1a, SP1b, SP2a, and SP2b. In FIGS. 12 and 13, the values of the horizontal direction and the vertical direction may be interval (Intv) of set to 450 nm between the search points SP1a, SP1b, SP2a, and SP2b. The selected pattern PA may have an interval (Intv) of (0, 0).

As illustrated in FIG. 12, the smallest etch skew (that is, the smallest effective ACI target) of the search points SP1a, SP1b, SP2a, and SP2b may be calculated continuously from 18 nm to 19 nm in the horizontal direction in the first to third rows. The smallest etch skew (that is, the smallest effective ACI target) of the search points SP1a, SP1b, SP2a, and SP2b may be calculated continuously from 18.25 nm or 18.5 nm to 19 nm in the horizontal direction in the fourth and fifth rows.

As illustrated in FIG. 12, the smallest etch skew (that is, the smallest effective ACI target) of the search points SP1a, SP1b, SP2a, and SP2b may be calculated continuously from 18 nm to 18.5 nm in a vertical direction in the first column. The smallest etch skew (that is, the smallest effective ACI target) of the search points SP1a, SP1b, SP2a, and SP2b may be calculated continuously from 18 nm or 18.5 nm to 19 nm in the vertical direction in the second to fourth column. The smallest etch skew (that is, the smallest effective ACI target) of the search points SP1a, SP1b, SP2a, and SP2b may be unchanged from 19 nm in the vertical direction in the fifth column.

Referring to FIG. 12, it may be determined that the smallest etch skew (that is, the smallest effective ACI target) of the search points SP1a, SP1b, SP2a, and SP2b may change in the first hatch portion HA1. As illustrated in FIG. 13, the greatest etch skew (that is, the greatest effective ACI target) of the search points SP1a, SP1b, SP2a, and SP2b may be calculated continuously from 18 nm to 19 nm in the horizontal direction in the first and second rows. The greatest etch skew (that is, the greatest effective ACI target) of the search points SP1a, SP1b, SP2a, and SP2b may be calculated continuously from 18.5 nm to 19 nm in the horizontal direction in the third row. The greatest etch skew (that is, the greatest effective ACI target) of the search points SP1a, SP1b, SP2a, SP2b may be calculated as 19 nm in the horizontal direction in the fourth and fifth rows.

As illustrated in FIG. 13, the greatest etch skew (that is, the greatest effective ACI target) of the search points SP1a, SP1b, SP2a, and SP2b may be calculated continuously from 18 nm to 19 nm in the vertical direction in the first and second columns. The greatest etch skew (that is, the greatest effective ACI target) of the search points SP1a, SP1b, SP2a, and SP2b may be calculated continuously from 18.5 nm to 19 nm in the vertical direction in the third column. The greatest etch skew (that is, the greatest effective ACI target) of the search points SP1a, SP1b, SP2a, and SP2b may be unchanged from 19 nm in the vertical direction in the fourth and fifth columns.

Referring to FIG. 13, it may be determined that the greatest etch skew (that is, the greatest effective ACI target) of the search points SP1a, SP1b, SP2a, and SP2b may change in a second hatch portion HA2. Referring to FIGS. 12 and 13, the etch skews (that is, effective ACI targets) of the search points SP1a and SP2a of FIG. 11 may be unchanged, and the etch skews (that is, effective ACI targets) of the search points SP1b and SP2b of FIG. 11 may be changed. Referring to FIGS. 12 and 13, a greatest line Max connecting the search points SP1b of the first sublayer Sub 1 of FIG. 11 may be determined as a first boundary line EB1 where the etch skew (that is, the effective ACI target) is changed.

Referring to FIGS. 12 and 13, a smallest line Min connecting the search points SP2b of the second sublayer Sub 2 of FIG. 11 may be determined as a second boundary line EB2 where the etch skew (that is, the effective ACI target) is changed. An intermediate line Avg between the first boundary line EB1 and the second boundary line (EB2) may be determined as a boundary line between the first sublayer Sub 1 and the second sublayer Sub 2 in the design layout.

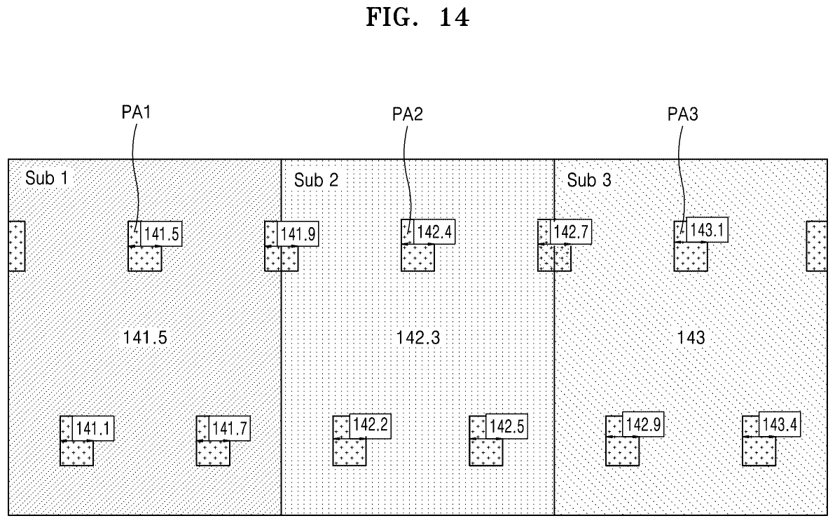

FIG. 14 is a diagram illustrating a result of one-dimensionally allocating an effective ACI target when a mask is manufactured, according to an embodiment. Specifically, as illustrated in FIG. 14, a design layout may be divided into a first sublayer Sub 1, a second sublayer Sub 2, and a third sublayer Sub 3 according to a lower structure layout of a semiconductor chip, that is, a lower structure. A preliminary ACI target of first patterns PA1 in the first sublayer Sub 1 may be 141.5 nm. A preliminary ACI target of second patterns PA2 in the second sublayer Sub 2 may be 142.3 nm. A preliminary ACI target of third patterns PA3 in the third sublayer Sub 3 may be 143 nm.

As illustrated in FIG. 14, when effective ACI targets are allocated according to the method described above, effective ACI targets of the first patterns PA1 in the first sublayer Sub 1 may be distributed from 141.1 nm to 141.7 nm, and effective ACI targets of the second patterns PA2 in the second sublayer Sub 2 may be distributed from 142.2 nm to 142.5 nm. Effective ACI targets of the first and second patterns PA1 and PA2 at a boundary between the first sublayer Sub 1 and the second sublayer Sub 2 may be 141.9 nm and may have an intermediate value of the effective ACI targets of the first patterns PA1 and the second patterns PA2.

As illustrated in FIG. 14, when effective ACI targets are allocated according to the method described above, effective ACI targets of the third patterns PA3 in the third sublayer Sub 3 may be distributed from 142.9 nm to 143.4 nm. Effective ACI targets of the second and third patterns PA2 and PA3 at a boundary between the second sublayer Sub 2 and the third sublayer Sub 3 may be 142.7 nm and may have an intermediate value of the effective ACI targets of the second patterns PA2 and the third patterns PA3. As described above, in the design layout of the inventive concept, the effective ACI targets of the first sublayer Sub 1, the second sublayer Sub 2, and the third sublayer Sub 3 may be continuously distributed according to a lower structure layout of a semiconductor chip, that is, a lower structure.

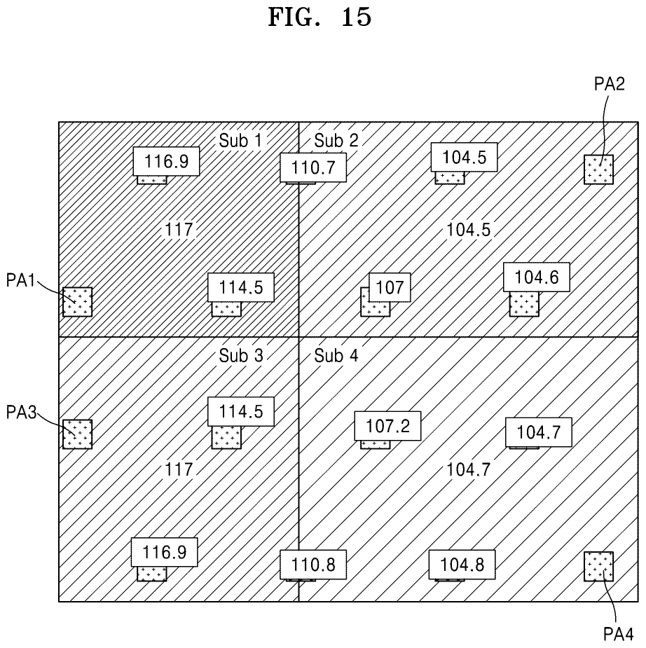

FIG. 15 is a diagram illustrating a result of two-dimensionally allocating an effective ACI target when a mask is manufactured, according to an embodiment. Specifically, as illustrated in FIG. 15, a design layout may be divided into a first sublayer Sub 1, a second sublayer Sub 2, a third sublayer Sub 3, and a fourth sublayer Sub 4 according to a lower structure layout of a semiconductor chip, that is, a lower structure.

A preliminary ACI target of first patterns PA1 in the first sublayer Sub 1 may be 117 nm. A preliminary ACI target of second patterns PA2 in the second sublayer Sub 2 may be 104.5 nm. A preliminary ACI target of third patterns PA3 in the third sublayer Sub 3 may be 117 nm. A preliminary ACI target of fourth patterns PA4 in the fourth sublayer Sub 4 may be 104.7 nm.

As illustrated in FIG. 15, when effective ACI targets are allocated according to the method described above, effective ACI targets of the first patterns PA1 in the first sublayer Sub 1 may be distributed from 114.5 nm to 116.9 nm, and effective ACI targets of the second patterns PA2 in the second sublayer Sub 2 may be distributed from 104.5 nm to 107 nm. The effective ACI targets of the first and second patterns PA1 and PA1 at a boundary between the first sublayer Sub 1 and the second sublayer Sub 2 may be 110.7 nm and may have an intermediate value of the effective ACI targets of the first patterns PA1 and the second patterns PA2.

As illustrated in FIG. 15, when effective ACI targets are allocated according to the method described above, effective ACI targets of the third patterns PA3 in the third sublayer Sub 3 may be distributed from 114.5 nm to 116.9 nm, and effective ACI targets of the fourth patterns PA4 in the fourth sublayer Sub 4 may be distributed from 104.7 nm to 107.2 nm. The effective ACI targets of the third and fourth patterns PA3 and PA4 at a boundary between the third sublayer Sub 3 and the fourth sublayer Sub 4 may be 110.8 nm and may have an intermediate value of the effective ACI targets of the third patterns PA3 and the fourth patterns PA4.

As described above, in the design layout of the inventive concept, the effective ACI targets of the first sublayer Sub 1, the second sublayer Sub 2, the third sublayer Sub 3, and the fourth sublayer Sub 4 may be continuously distributed according to a lower structure layout of a semiconductor chip, that is, a lower structure.

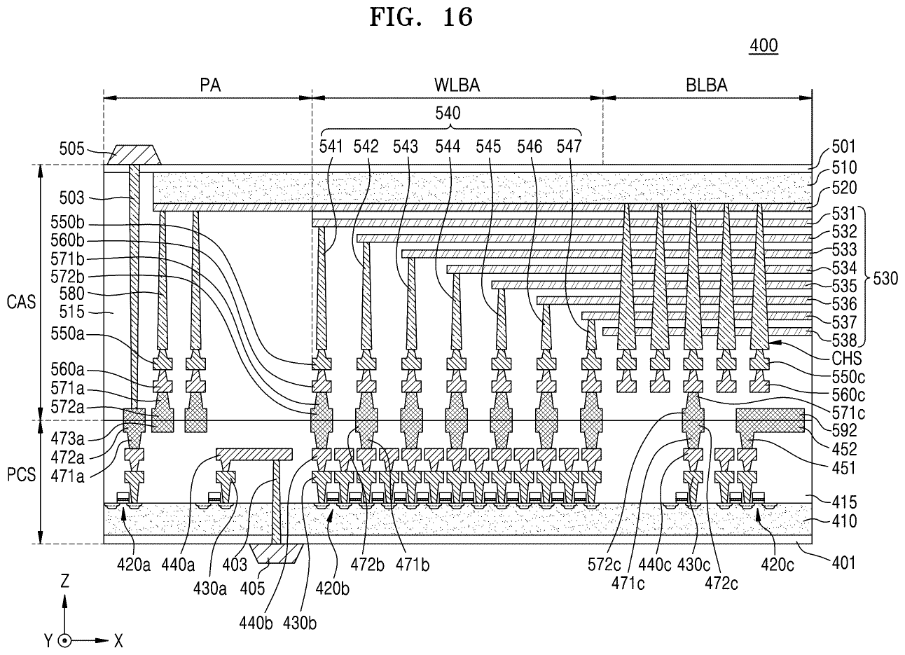

FIG. 16 is a cross-sectional view illustrating a semiconductor chip according to an embodiment. Specifically, a semiconductor chip 400 may have a chip to chip (C2C) structure. In some embodiments, the semiconductor chip 400 may be formed by using a mask manufactured by the mask manufacturing method according to the inventive concept described above. In the C2C structure, an upper chip including a cell array structure (CAS) is on a first wafer, a lower chip having a peripheral circuit structure (PCS) including a peripheral circuit is on a second wafer different from the first wafer, and the upper chip may be connected to the lower chip by using a bonding method.

For example, the bonding method may be used to electrically connect a bonding metal formed on an uppermost metal layer of the upper chip to a bonding metal formed on an uppermost metal layer of the lower chip. For example, when the bonding metal is formed of copper (Cu), the bonding method may be a Cu—Cu bonding method, and the bonding metal may include aluminum (Al) or tungsten (W).

Although one cell array structure CAS is bonded onto a peripheral circuit structure PCS, upper chips including a plurality of cell array structures may be bonded onto the peripheral circuit structure PCS. Each of the peripheral circuit structure PCS and the cell array structure CAS of the semiconductor chip 400 may include an external pad bonding region PA, a word line bonding region WLBA, and a bit line bonding region BLBA.

The peripheral circuit structure PCS may include a first substrate 410, an interlayer insulating layer 415, a plurality of circuit elements 420a, 420b, and 420c formed on the first substrate 410, first metal layers 430a, 430b, and 430c respectively connected to the plurality of circuit elements 420a, 420b, and 420c, and second metal layers 440a, 440b, and 440c respectively formed on the first metal layers 430a, 430b, and 430c.

The circuit elements 420a, 420b, and 420c may each include a transistor. In one embodiment, the first metal layers 430a, 430b, and 430c may be formed of tungsten having a relatively high resistivity, and the second metal layers 440a, 440b, and 440c may be formed of copper having a relatively low resistivity.

Although FIG. 12 illustrates only the first metal layers 430a, 430b, and 430c and the second metal layers 440a, 440b, and 440c, the inventive concept is not limited thereto, and at least one metal layer may be further formed on each of the second metal layers 440a, 440b, and 440c. At least one metal layer formed on each of the second metal layers 440a, 440b, and 440c may be formed of aluminum having a lower specific resistance than copper forming the second metal layers 440a, 440b, and 440c.

The interlayer insulating layer 415 may be on the first substrate 410 to cover the plurality of circuit elements 420a, 420b, and 420c, the first metal layers 430a, 430b, and 430c, and the second metal layers 440a, 440b, and 440c, and may include an insulating material, such as silicon oxide or silicon nitride.

Lower bonding metal layers 471b and 472b may be formed on second metal layer 440b in the word line bonding region WLBA. In the word line bonding region WLBA, the lower bonding metal layers 471b and 472b of the peripheral circuit structure PCS may be electrically connected to upper bonding metal layers 571b and 572b of the cell array structure CAS by a bonding method, and the lower bonding metal layers 471b and 472b and the upper bonding metal layers 571b and 572b may be formed of aluminum, copper, or tungsten.

The cell array structure CAS may provide at least one memory cell block. The cell array structure CAS may include a second substrate 510 and a common source line 520. A plurality of word lines 531 to 538 (530) may be stacked on the second substrate 510 in a direction perpendicular to an upper surface of the second substrate 510 (the Z direction). String select lines and a ground select line may be over and under the plurality of word lines 530, and the plurality of word lines 530 may be between the string select lines and the ground select line.

In the bit line bonding region BLBA, a channel structure CHS may extend in a direction (the Z direction) perpendicular to an upper surface of the second substrate 510 and penetrate the plurality of word lines 530, the string select lines, and the ground select line. The channel structure CHS may be formed by the mask manufactured by the mask manufacturing method according to the inventive concept described above.

The channel structure CHS may include a data storage layer, a channel layer, and a buried insulating layer, and the channel layer may be electrically connected to a first metal layer 550c and a second metal layer 560c. For example, the first metal layer 550c may be a bit line contact, and the second metal layer 560c may be a bit line 560c. In one embodiment, the bit line may extend in a second direction (the Y direction) parallel to the upper surface of the second substrate 510.

In one embodiment, a region where the channel structure CHS, the bit line, and so on are arranged may be defined as the bit line bonding region BLBA. The bit line may be electrically connected to circuit elements 420c in the peripheral circuit structure PCS of the bit line bonding region BLBA. For example, the bit line may be connected to upper bonding metal layers 571c and 572c in the peripheral circuit structure PCS, and the upper bonding metal layers 571c and 572c may be connected to lower bonding metal layers 471c and 472c connected to the circuit elements 420c.

In the word line bonding region WLBA, the plurality of word lines 530 may extend in a first direction (the X direction) parallel to the upper surface of the second substrate 510 and may be connected to a plurality of cell contact plugs 541 to 547 (540). In some embodiments, the cell contact plugs 541-547 (540) may be formed by the mask manufactured by the mask manufacturing method according to the inventive concept described above.

The plurality of word lines 530 and the plurality of cell contact plugs 540 may be connected to pads provided by extending at least some of the word lines 530 with different lengths in the first direction (the X direction). A first metal layer 550b and a second metal layer 560b may be sequentially connected to an upper portion of each of the plurality of cell contact plugs 540 connected to the plurality of word lines 530. The plurality of cell contact plugs 540 may be connected to the peripheral circuit structure PCS through the upper bonding metal layers 571b and 572b of the cell array structure CAS in the word line bonding region WLBA and the lower bonding metal layers 471b and 472b of the peripheral circuit structure PCS in the word line bonding region WLBA. The plurality of cell contact plugs 540 may be electrically connected to the circuit elements 420b of the peripheral circuit structure PCS.

Common source line contact plugs 580 may be in the external pad bonding region PA. The common source line contact plugs 580 may be formed of a conductive material such as a metal, a metal compound, or polysilicon, and may be electrically connected to the common source line 520. The first metal layer 550a and the second metal layer 560a may be sequentially stacked on the common source line contact plug 580. For example, a region where the common source line contact plugs 580, the first metal layers 550a, and the second metal layers 560a are arranged may be defined as the external pad bonding region PA.

The lower bonding metal layers 471a and 472a may be formed in the external pad bonding region PA. In the external pad bonding region PA, the lower bonding metal layers 471a and 472a of the peripheral circuit structure PCS may be electrically connected to the upper bonding metal layers 571a and 572a of the cell array structure CAS by a bonding method, and the lower bonding metal layers 471a and 472a and the upper bonding metal layers 571a and 572a may be formed of aluminum, copper, or tungsten.

In addition, a first input/output pad 405 and a second input/output 505 may be in the external pad bonding region PA. A lower insulating layer 401 covering a lower surface of the first substrate 410 may be formed under the first substrate 410, and the first input/output pad 405 may be formed on the lower insulating layer 401. The first input/output pad 405 may be connected to at least one of the plurality of circuit elements 420a, 420b, and 420c arranged in the peripheral circuit structure PCS through a first input/output contact plug 403, and may be separated from the first substrate 410 by the lower insulating layer 401. In addition, a side insulating layer may be between the first input/output contact plug 403 and the first substrate 410 to electrically separate the first input/output contact plug 403 from the first substrate 410.

An upper insulating layer 501 covering the upper surface of the second substrate 510 may be formed on the second substrate 510, and the second input/output pads 505 may be on the upper insulating layer 501. The second input/output pad 505 may be connected to at least one of the plurality of circuit elements 420a, 420b, and 420c in the peripheral circuit structure PCS through the second input/output contact plug 503.

In one embodiment, the second substrate 510 and a common source line 520 may not be in a region where the second input/output contact plug 503 is arranged. In addition, the second input/output pad 505 may not overlap the plurality of word lines 530 in a third direction (the Z direction). The second input/output contact plug 503 may be separated from the second substrate 510 in a direction parallel to the upper surface of the second substrate 510 and may be connected to the second input/output pad 505 by penetrating the interlayer insulating layer 515 of the cell array structure CAS.

In some embodiments, the first input/output pad 405 and the second input/output pad 505 may be selectively formed. For example, the semiconductor chip 400 may include only the first input/output pad 405 over the first substrate 410 or may include only the second input/output pad 505 over the second substrate 510. Alternatively, the semiconductor chip 400 may also include both the first input/output pad 405 and the second input/output pad 505.

In each of the external pad bonding region PA and the bit line bonding region BLBA included in each of the cell array structure CAS and the peripheral circuit structure PCS, a metal pattern of the uppermost metal layer may be formed as a dummy pattern, or the uppermost metal layer may not be formed. In the external pad bonding region PA of the semiconductor chip 400, the lower metal patterns 472a and 473a having the same shape as the upper metal pattern 572a of the cell array structure CAS may be formed on the uppermost metal layer of the peripheral circuit structure PCS to correspond to the upper metal pattern 572a formed on the uppermost metal layer of the cell array structure CAS. The lower metal pattern 473a formed on the uppermost metal layer of the peripheral circuit structure PCS may not be connected to a separate contact in the peripheral circuit structure PCS. Similarly, in the external pad bonding region PA, the upper metal pattern 572a having the same shape as the lower metal pattern 473a of the peripheral circuit structure PCS may be formed on the upper metal layer of the cell array structure CAS to correspond to the lower metal pattern 473a formed on the uppermost metal layer of the peripheral circuit structure PCS.

The lower bonding metal layers 471b and 472b may be formed on the second metal layer 440b of the word line bonding region WLBA. In the word line bonding region WLBA, the lower bonding metal layers 471b and 472b of the peripheral circuit structure PCS may be electrically connected to the upper bonding metal layers 571b and 572b of the cell array structure CAS by a bonding method.

In addition, in the bit line bonding region BLBA, an upper metal pattern 592 having the same shape as a lower metal pattern 452 of the peripheral circuit structure PCS may be formed on the uppermost metal layer of the cell array structure CAS to correspond to the lower metal pattern 452 formed on the uppermost metal layer of the peripheral circuit structure PCS. A contact may not be formed on the upper metal pattern 592 formed on the uppermost metal layer of the cell array structure CAS. The lower metal pattern 452 of the peripheral circuit structure PCS may be electrically connected to the circuit element 420c through a metal layer 451.

According to the mask manufacturing method of the inventive concept, an ACI target of a pattern of a design layout on a mask may be precisely allocated when or before PPC is performed. Accordingly, the optical proximity effect and loading effect may be predicted and analyzed in advance, and the pattern of the design layout on the mask may be easily corrected according to a result of the analysis. In addition, according to the semiconductor chip manufacturing method of the inventive concept, a semiconductor chip may be reliably manufactured by using the mask manufacturing method described above.

Although the inventive concept is described above with reference to the embodiments illustrated in the drawings, the embodiments are merely examples, and those skilled in the art will understand that various modifications, substitutions, and implementation of other equivalent embodiments may be made therefrom. The embodiments described above should be understood in all respects as illustrative and not restrictive. The true technical protection scope of the inventive concept should be determined by the technical idea of the appended claims.

While the inventive concept has been particularly illustrated and described with reference to embodiments thereof, it will be understood that various changes in form and details may be made therein without departing from the spirit and scope of the following claims.

What is claimed is:

1. A method of manufacturing a mask for semiconductor processing, comprising:
generating a design layout;
allocating an effective after clean inspection (ACI) target to the design layout, according to a location of a lower structure layout of a semiconductor chip; and
performing process proximity correction (PPC) on the design layout according to the effective ACI target.

2. The method of claim 1, wherein said allocating comprises obtaining the effective ACI target by performing a numerical integration on a preliminary ACI target of the design layout based on: (i) etch skew measurement data according to a location of a lower structure layout of the semiconductor chip, and (ii) a probability density function of the design layout according to the location of the lower structure layout.

3. The method of claim 2, wherein the preliminary ACI target includes a binary ACI target according to the location of the lower structure layout of the semiconductor chip.

4. The method of claim 2, wherein the probability density function includes a Gaussian blur function.

5. The method of claim 2, wherein said allocating comprises:
selecting a pattern of the design layout according to the location of the lower structure layout of the semiconductor chip;
allocating a plurality of search points based on the selected pattern of the design layout; and
obtaining an effective ACI target of the selected pattern of the design layout by performing the numerical integration on the preliminary ACI target and a probability density function of the search points.

6. The method of claim 1, wherein the lower structure layout of the semiconductor chip includes a stacked body in which a plurality of sublayers are stacked, and the design layout includes a plurality of contact patterns that are arranged on the stacked body and separated from each other.

7. The method of claim 1, wherein said allocating comprises:
dividing the lower structure layout of the semiconductor chip into a first lower structure layout having a first sublayer and a second lower structure layout having a second sublayer; and
repeatedly changing the effective ACI target of the design layout through a boundary between the first lower structure layout and the second lower structure layout.

8. The method of claim 1, further comprising performing optical proximity correction (OPC) on the design layout according to the effective ACI target.

9. A mask manufacturing method, comprising:
generating a design layout;
allocating an effective after clean inspection (ACI) target to the design layout by:
generating a lower structure layout of a semiconductor chip;
receiving etch skew measurement data on the design layout based on the lower structure layout of the semiconductor chip;
allocating a preliminary ACI target of the design layout according to a location of the lower structure layout of the semiconductor chip based on the etch skew measurement data; and
obtaining the effective ACI target by performing numerical integration on the preliminary ACI target and a probability density function of the design layout according to the location of the lower structure layout of the semiconductor chip; and
performing process proximity correction (PPC) on the design layout according to the effective ACI target.

10. The method of claim 9, said allocating further includes:
dividing the lower structure layout of the semiconductor chip into a first lower structure layout having a first sublayer and a second lower structure layout having a second sublayer; and
repeatedly changing the effective ACI target of the design layout through a boundary between the first lower structure layout and the second lower structure layout.

11. The method of claim 9, wherein said allocating further includes:
selecting a pattern of the design layout according to the location of the lower structure layout of the semiconductor chip;
allocating a plurality of search points based on a selected pattern of the design layout; and
obtaining an effective ACI target of the selected pattern of the design layout by performing the numerical integration on the preliminary ACI target and a probability density function of the search points.

12. The method of claim 9, wherein the preliminary ACI target includes a binary ACI target according to the location of the lower structure layout of the semiconductor chip.

13. The method of claim 9, wherein the probability density function includes Gaussian blur function.

14. The method of claim 9, wherein the lower structure layout of the semiconductor chip includes a stacked body in which a plurality of sublayers are stacked, and the design layout includes a plurality of contact patterns that are arranged on the stacked body and separated from each other.

15. The method of claim 9, further comprising performing optical proximity correction (OPC) on the design layout according to the effective ACI target.

16. A semiconductor chip manufacturing method, comprising:
generating a design layout;
allocating an effective after clean inspection (ACI) target to the design layout by:
generating a lower structure layout of a semiconductor chip;
receiving etch skew measurement data on the design layout based on the lower structure layout of the semiconductor chip;
allocating a preliminary ACI target of the design layout according to a location of the lower structure layout of the semiconductor chip based on the etch skew measurement data; and
obtaining the effective ACI target by performing numerical integration on the preliminary ACI target and a probability density function of the design layout according to the location of the lower structure layout of the semiconductor chip;
performing process proximity correction (PPC) on the design layout according to the effective ACI target;
performing optical proximity correction (OPC) on the design layout according to the effective ACI target;
manufacturing a mask by using a design layout obtained by performing the OPC; and
manufacturing a semiconductor chip by using the mask.

17. The method of claim 16, wherein said allocating further includes:
dividing the lower structure layout of the semiconductor chip into a first lower structure layout having a first sublayer and a second lower structure layout having a second sublayer; and
repeatedly changing the effective ACI target of the design layout through a boundary between the first lower structure layout and the second lower structure layout.

18. The method of claim 16, wherein said allocating further includes:
selecting a pattern of the design layout according to the location of the lower structure layout of the semiconductor chip;
allocating a plurality of search points based on a selected pattern of the design layout; and
obtaining an effective ACI target of the selected pattern of the design layout by performing the numerical integration on the preliminary ACI target and a probability density function of the search points.

19. The method of claim 18, wherein the preliminary ACI target includes a binary ACI target according to the location of the lower structure layout of the semiconductor chip, and the probability density function includes Gaussian blur function.

20. The method of claim 18, wherein the lower structure layout of the semiconductor chip includes a stacked body in which a plurality of sublayers are stacked, and the design layout includes a plurality of contact patterns that are arranged on the stacked body and separated from each other.
